(19) United States
(12) Patent Application Publication
(10) Pub. No.: US 2024/0147788 A1
(43) Pub. Date: May 2, 2024

(54) DISPLAY APPARATUS AND METHOD OF MANUFACTURING THE SAME

(71) Applicant: SAMSUNG DISPLAY CO., LTD., Yongin-si (KR)

(72) Inventor: Daehong KIM, Yongin-si (KR)

(21) Appl. No.: 18/224,721

(22) Filed: Jul. 21, 2023

(30) Foreign Application Priority Data
Oct. 27, 2022 (KR) 10-2022-0140504

(51) Int. Cl. H10K 59/131; H10K 59/12; H10K 59/80

(52) U.S. Cl. CPC H10K 59/131; H10K 59/1201; H10K 59/873

(57) ABSTRACT

A display apparatus includes: a substrate including the opening area, a display area surrounding at least a portion of the opening area, and a middle area between the opening area and the display area, a display element arranged in the display area and comprising a pixel electrode, an opposite electrode on the pixel electrode, and an intermediate layer arranged between the pixel electrode and the opposite electrode, and a metal unit arranged in the middle area and arranged between the substrate and the intermediate layer extending to the middle area.

This application claims priority to Korean Patent Application No. 10-2022-0140504, filed on Oct. 27, 2022, and all the benefits accruing therefrom under 35 U.S.C. § 119, the content of which in its entirety is herein incorporated by reference.

### BACKGROUND

### 1. Field

One or more embodiments relate to a display apparatus and a method of manufacturing the same, and more particularly, to a display apparatus having improved reliability and a method of manufacturing the same.

### 2. Description of the Related Art

The usage of a display apparatus has diversified. Also, the display apparatus has become thinner and lighter, and thus, the range of uses of the display apparatus has expanded.

As the area occupied by a display area in the display apparatus has increased, various functions connected to or associated with the display apparatus has been added. As a method of increasing the display area and adding various functions, research has been conducted into the display apparatus including a display area in which various components are arranged.

### SUMMARY

One or more embodiments include a display apparatus including a display area having an area for arranging various types of components, the display apparatus having improved reliability, and a method of manufacturing the display apparatus. However, this aspect is an example and does not limit the scope of the disclosure.

Additional aspects will be set forth in part in the description which follows and, in part, will be apparent from the description, or may be learned by practice of the presented embodiments of the disclosure.

According to one or more embodiments, a display apparatus includes a substrate including an opening area, a display area surrounding at least a portion of the opening area, and a middle area between the opening area and the display area, a display element arranged in the display area and including a pixel electrode, an opposite electrode on the pixel electrode, and an intermediate layer arranged between the pixel electrode and the opposite electrode, and a metal unit arranged in the middle area and arranged between the substrate and the intermediate layer extending to the middle area.

The display apparatus may further include an inorganic insulating layer arranged between the substrate and the intermediate layer to correspond to the display area and the middle area, wherein the metal unit may be arranged between the inorganic insulating layer and the intermediate layer.

The metal unit may include aluminum (Al) or silver (Ag).

The display apparatus may further include a first partition wall arranged in the middle area to surround the opening area, wherein the metal unit may be arranged between the first partition wall and the display area.

An opening portion penetrating the intermediate layer may be defined in the intermediate layer, and the opening portion may be arranged between the first partition wall and the opening area.

The metal unit may be arranged to be apart from the opening portion.

The display apparatus may further include a second partition wall arranged in the middle area to be apart from the first partition wall, wherein the opening portion may include a first opening arranged between the first partition wall and the second partition wall and a second opening arranged between the second partition wall and the opening area.

The display apparatus may further include an inorganic encapsulation layer arranged on the intermediate layer to correspond to the display area and the middle area, wherein the inorganic encapsulation layer directly may contact an inorganic insulating layer exposed through the opening portion.

The display apparatus may further include a capping layer arranged between the opposite electrode and the inorganic encapsulation layer.

The intermediate layer may include a first common layer, an emission layer, and a second common layer, which are sequentially arranged on the pixel electrode.

The display apparatus may further include a line portion arranged in the display area to be adjacent to the middle area so as to bypass the opening area.

According to one or more embodiments, a method of manufacturing a display apparatus includes: preparing a substrate including a certain area, a display area surrounding at least a portion of the certain area, and a middle area between the certain area and the display area, forming a sacrificial metal layer on a laser irradiation region in the middle area, forming a metal unit including a first material on a region in the middle area, except for the laser irradiation region, forming an intermediate layer to cover the sacrificial metal layer, forming an opposite electrode to cover the intermediate layer, and removing the sacrificial metal layer and a portion of the intermediate layer formed on the sacrificial metal layer by irradiating a laser ray onto the laser irradiation region.

The forming of the sacrificial metal layer may include forming a metal layer including the first material and removing the first material of the metal layer.

The method may further include, after the forming of the metal unit, determining whether or not the first material of the sacrificial metal layer remains, by comparing inspection values with respect to the first material of the sacrificial metal layer and the first material of the metal unit.

The inspection values may be values of reflected light extracted through an optical inspector.

The first material may include aluminum (Al) or silver (Ag).

The method may further include, after the forming of the metal unit, etching a portion of the sacrificial metal layer.

An opening portion of the intermediate layer may be formed by removing the portion of the intermediate layer together with the sacrificial metal layer.

The method may further include forming an inorganic encapsulation layer on the opposite electrode, wherein the inorganic encapsulation layer may be in direct contact with an inorganic insulating layer exposed through the opening portion of the intermediate layer.

The method may further include removing a portion of the opposite electrode by irradiating the laser ray onto the laser irradiation region, and forming a through-hole corresponding to the certain area of the substrate, wherein the portion of the opposite electrode may be simultaneously removed when the sacrificial metal layer is removed.

These general and specific embodiments may be implemented by using a system, a method, a computer program, or a combination of the system, the method, and the computer program.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic perspective view of a display apparatus according to an embodiment;

FIG. 2 is a schematic cross-sectional view of a display apparatus according to an embodiment;

FIG. 3 is a schematic plan view of a display panel according to an embodiment;

FIG. 4 is a schematic equivalent circuit diagram of any one pixel included in a display panel according to an embodiment;

FIG. 5 is a plan view of a portion of a display panel according to an embodiment;

FIG. 6 is a schematic cross-sectional view of a portion of a display area of a display apparatus according to an embodiment;

FIG. 7 is an enlarged plan view of region D of FIG. 5;

FIGS. 8A and 8B are schematic cross-sectional views of portions of a display area and a middle area of a display apparatus according to an embodiment;

FIG. 9 is an enlarged cross-sectional view of region E of FIG. 8A;

FIG. 10 is a schematic cross-sectional view of a portion of a display panel according to an embodiment;

FIGS. 11A through 11F are schematic cross-sectional views for describing part of a manufacturing process of a display apparatus, according to an embodiment; and

FIG. 12 is a cross-sectional view showing reflection of a laser ray, which may occur in a manufacturing process of a display apparatus.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

While the disclosure is capable of various modifications and alternative forms, embodiments thereof are shown by way of example in the drawings and will herein be described in detail. Effects and characteristics of the disclosure, and realizing methods thereof will become apparent by referring to the drawings and embodiments described in detail below. However, the disclosure is not limited to the embodiments disclosed hereinafter and may be realized in various forms.

Hereinafter, embodiments of the disclosure will be described in detail by referring to the accompanying drawings. In descriptions with reference to the drawings, the same reference numerals are given to elements that are the same or substantially the same and descriptions will not be repeated.

It will be understood that although the terms “first,” “second,” etc. may be used herein to describe various components, these components should not be limited by these terms. These components are only used to distinguish one component from another.

As used herein, the singular expressions “a,” “an,” and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components.

It will be understood that when a layer, region, or element is referred to as being formed “on” another layer, area, or element, it can be directly or indirectly formed on the other layer, region, or element. That is, for example, intervening layers, regions, or elements may be present.

In the embodiments hereinafter, it will be understood that when an element, an area, or a layer is referred to as being connected to another element, area, or layer, it can be directly and/or indirectly connected to the other element, area, or layer. For example, it will be understood in this specification that when an element, an area, or a layer is referred to as being in contact with or being electrically connected to another element, area, or layer, it can be directly and/or indirectly in contact with or electrically connected to the other element, area, or layer.

In this specification, the expression “A and/or B” may indicate A, B, or A and B. Also, the expression “at least one of A and B” may indicate A, B, or A and B.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

Sizes of elements in the drawings may be exaggerated for convenience of explanation. For example, sizes and thicknesses of the elements in the drawings are randomly indicated for convenience of explanation, and thus, the disclosure is not necessarily limited to the illustrations of the drawings.

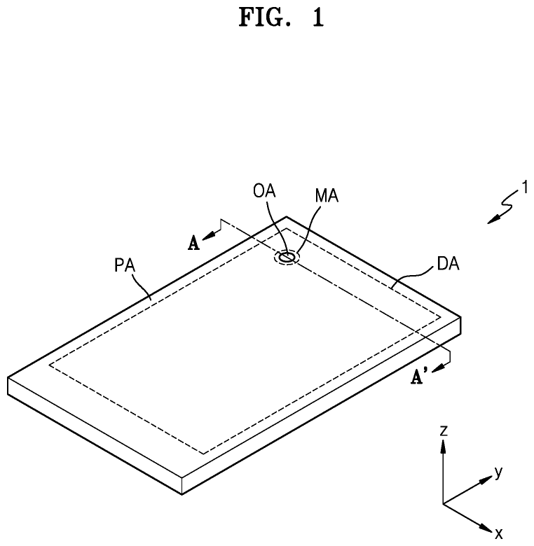

FIG. 1 is a schematic perspective view of a display apparatus 1 according to an embodiment.

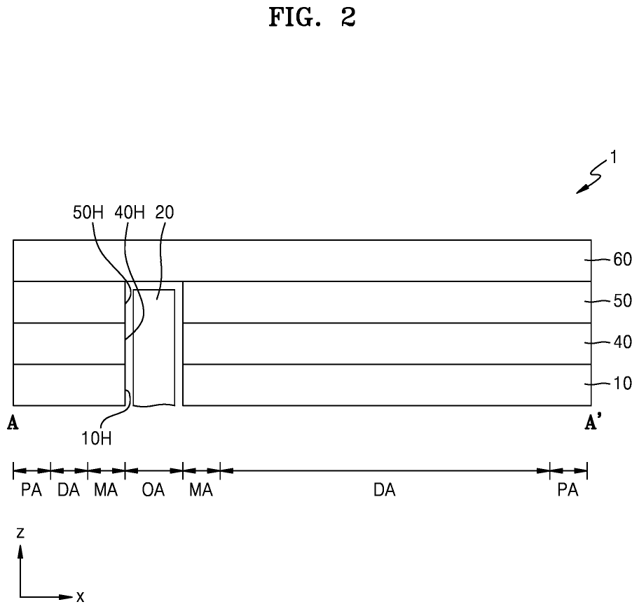

Referring to FIG. 1, the display apparatus 1 may include an opening area OA (or a transmission area or a first area) and a display area DA at least partially surrounding the opening area OA. The display apparatus 1 may provide a certain image by using light emitted from a plurality of pixels arranged in the display area DA. The opening area OA may be partially or entirely surrounded by the display area DA. The opening area OA may be an area where a component to be described below with reference to FIG. 2 may be arranged.

A middle area MA may be arranged between the opening area OA and the display area DA, and the display area DA may be surrounded by an outer area PA. The middle area MA and the outer area PA may be types of non-display areas in which pixels are not arranged. The middle area MA may be partially or entirely surrounded by the display area DA, and the display area DA may be entirely surrounded by the outer area PA.

Hereinafter, an organic light-emitting display apparatus is described as an example of the display apparatus 1 according to an embodiment. However, the display apparatus according to an embodiment is not limited thereto. According to another embodiment, the display apparatus 1 according to the disclosure may include a display apparatus, such as a quantum dot light-emitting display apparatus. For example, an emission layer of a display element included in the display apparatus 1 may include an organic material, an inorganic material, quantum dots, an organic material and quantum dots, or an inorganic material and quantum dots.

FIG. 1 illustrates that one opening area OA is provided and has an approximately circular shape. However, the disclosure is not limited thereto. There may be two or more opening areas OA, and each of the opening areas OA may be variously modified to have a circular, oval, polygonal, diamond, or bar shape.

Also, FIG. 1 illustrates that the display apparatus 1 includes the display area DA formed as a flat surface. However, at least a portion of the display apparatus 1 may be foldable, bendable, or rollable. In this case, at least a portion of the display area DA may have a curved surface.

FIG. 2 is a schematic cross-sectional view of the display apparatus 1 according to an embodiment, and FIG. 2 may correspond to a cross-section of the display apparatus 1 taken along line A-A′ of FIG. 1.

Referring to FIG. 2, the display apparatus 1 may include a display panel 10 and an input sensing layer 40 and an optical functional layer 50 which may be arranged on the display panel 10, and the display panel 10, the input sensing layer 40, and the optical functional layer 50 may be covered by a window 60. The display apparatus 1 may include various types of electronic devices, such as a mobile phone, a notebook computer, a smart watch, etc.

The display panel 10 may display an image. The display panel 10 may include pixels arranged in the display area DA. The pixels may include a display element and a pixel circuit connected to the display element. The display element may include an organic light-emitting diode, a quantum dot organic light-emitting diode, etc.

The input sensing layer 40 may obtain coordinate information based on an external input, for example, a touch event. The input sensing layer 40 may include a sensing electrode or a touch electrode and trace lines connected to the sensing electrode or the touch electrode. The input sensing layer 40 may be arranged above the display panel 10. The input sensing layer 40 may sense an external input by using a mutual cap method and/or a self-cap method.

The input sensing layer 40 may be directly formed on the display panel 10 or may be separately formed from the display panel 10 and coupled to the display panel 10 through an adhesive layer, such as an optical clear adhesive. For example, the input sensing layer 40 may be continuously formed after a process of forming the display panel 10. In this case, the input sensing layer 40 may be understood as a portion of the display panel 10, and an adhesive layer may not be arranged between the input sensing layer 40 and the display panel 10. FIG. 2 illustrates that the input sensing layer 40 is arranged between the display panel 10 and the optical functional layer 50. However, according to another embodiment, the input sensing layer 40 may be arranged above the optical functional layer 50.

The optical functional layer 50 may include a reflection prevention layer. The reflection prevention layer may reduce the reflectivity of light (external light) incident toward the display panel 10 from the outside through the window 60. The reflection prevention layer may include a phase retarder and a polarizer. According to another embodiment, the reflection prevention layer may include a black matrix and color filters. Also, the optical functional layer 50 may include a lens layer. The lens layer may increase the extraction efficiency of light emitted from the display panel 10 or reduce the color deviation. The optical functional layer 50 may include both of the reflection prevention layer and the lens layer described above or any one of the reflection prevention layer and the lens layer.

According to an embodiment, the optical functional layer 50 may be continuously formed after the display panel 10 and/or the input sensing layer 40 are/is formed. In this case, an adhesive layer may not be arranged between the optical functional layer 50 and the display panel 10 and/or between the optical functional layer 50 and the input sensing layer 40.

The display panel 10, the input sensing layer 40, and/or the optical functional layer 50 may define an opening therein. With respect to this aspect, FIG. 2 illustrates that the display panel 10, the input sensing layer 40, and the optical functional layer 50 define a first opening 10H, a second opening 40H, and a third opening 50H therein, respectively, and the first to third openings 10H, 40H, and 50H overlap each other in a plan view. The first to third openings 10H, 40H, and 50H may be arranged to correspond to the opening area OA.

According to another embodiment, one or more of the display panel 10, the input sensing layer 40, and the optical functional layer 50 may not include an opening. For example, any one or two components selected from the display panel 10, the input sensing layer 40, and the optical functional layer 50 may not include an opening.

As described above, the opening area OA may be a type of component area (for example, a sensor area, a camera area, a speaker area, etc.) in which a component 20 for adding various functions to the display apparatus 1 is arranged. The component 20 may be arranged in the first to third openings 10H, 40H, and 50H, as illustrated in FIG. 2. Alternatively, the component 20 may be arranged below the display panel 10.

The component 20 may include an electronic element. For example, the component 20 may include an electronic element using light or sound. For example, the electronic element may include a sensor configured to output or/and receive light, such as an infrared sensor, a camera configured to receive light and capture an image, a sensor configured to output and sense light or sound to measure a distance or recognize a fingerprint, a small lamp configured to output light, a speaker configured to output sound, etc. In the case of the electronic element using light, the electronic element may use light of various wavelength ranges, such as visible rays, infrared rays, ultraviolet rays, etc. According to some embodiments, the opening area OA may be a transmission area through which light output from the component 20 to the outside or proceeding from the outside toward the electronic element may be transmitted.

According to another embodiment, when the display apparatus 1 is used as a smart watch or a vehicle dashboard, the component 20 may be a member, such as hands of a clock or hands indicating certain information (for example, a vehicle speed, etc.). When the display apparatus 1 includes clock hands or a vehicle dashboard, the component 20 may penetrate through the window 60 and may be exposed to the outside, and the window 60 may define an opening corresponding to the opening area OA therein.

The component 20 may include (a) component(s) associated with a function of the display panel 10 or may include an accessory component, etc., increasing an aesthetic sense of the display panel 10.

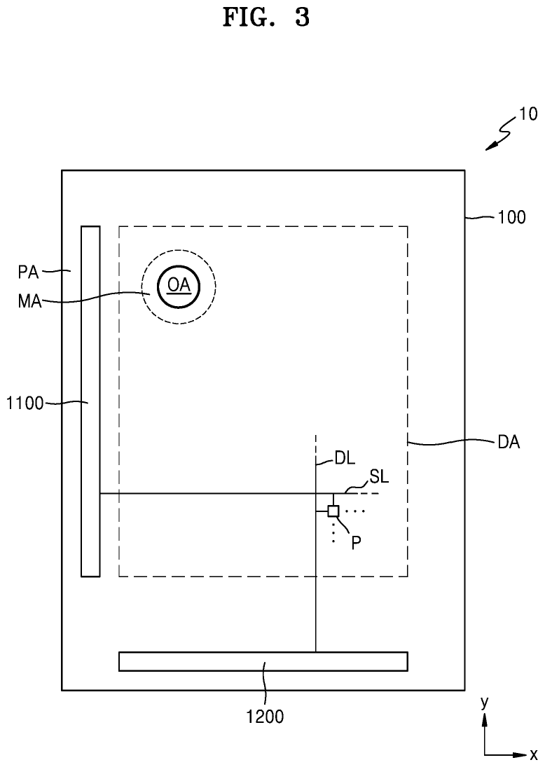

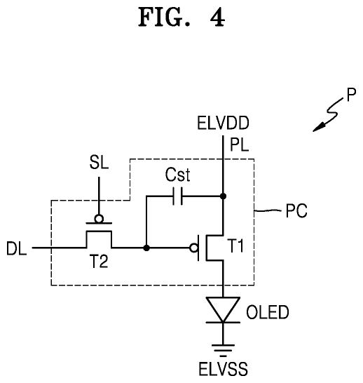

FIG. 3 is a schematic plan view of the display panel 10 according to an embodiment, and FIG. 4 is a schematic equivalent circuit diagram of any one pixel included in the display panel 10 according to an embodiment. As used herein, the plan view is a view in the z direction.

Referring to FIG. 3, the display panel 10 may include the opening area OA, the display area DA, the middle area MA, and the outer area PA. For convenience of explanation, this may indicate that a substrate 100 of the display panel 10 may include the opening area OA, the display area DA, the middle area MA, and the outer area PA.

The display panel 10 may include a plurality of pixels P arranged in the display area DA. As illustrated in FIG. 4, each pixel P may include a pixel circuit PC and an organic light-emitting diode OLED, which is a display element connected to the pixel circuit PC. The pixel circuit PC may include a first thin-film transistor T1, a second thin-film transistor T2, and a storage capacitor Cst. Each pixel PX may emit for example, red, green, blue, or white light through the organic light-emitting diode OLED.

The second thin-film transistor T2 may be a switching thin-film transistor, may be connected to a scan line SL and a data line DL, and may be configured to transmit, to the first thin-film transistor T1, a data voltage provided from the data line DL, based on a switching voltage provided from the scan line SL. The storage capacitor Cst may be connected to the second thin-film transistor T2 and a driving voltage line PL and may be configured to store a voltage corresponding to a difference between a voltage received from the second thin-film transistor T2 and a first power voltage ELVDD supplied to the driving voltage line PL.

The first thin-film transistor T1 may be a driving thin-film transistor, may be connected to the driving voltage line PL and the storage capacitor Cst, and may be configured to control a driving current flowing from the driving voltage line PL through the organic light-emitting diode OLED, according to a value of the voltage stored in the storage capacitor Cst. The organic light-emitting diode OLED may emit light having a certain brightness according to the driving current. An opposite electrode (for example, a cathode) of the organic light-emitting diode OLED may receive a second power voltage ELVSS.

FIG. 4 illustrates that the pixel circuit PC includes two thin-film transistors and one storage capacitor. However, the disclosure is not limited thereto. The number of thin-film transistors and the number of storage capacitors may be variously modified according to the design of the pixel circuit PC. For example, the pixel circuit PC may include two thin-film transistors, as described above, or four, five, or more thin-film transistors. According to an embodiment, the pixel circuit PC may include seven thin-film transistors and one storage capacitor.

Referring to FIG. 3 again, the middle area MA may surround the opening area OA in a plan view. The middle area MA is an area in which a display element emitting light, such as an organic light-emitting diode, is not arranged, and signal lines configured to provide signals to the pixels P arranged around the opening area OA may cross the middle area MA. A scan driver 1100 configured to provide a scan signal to each pixel P, a data driver 1200 configured to provide a data signal to each pixel P, main power lines (not shown) configured to provide the first power voltage ELVDD and the second power voltage ELVSS, etc. may be arranged in the outer area PA. FIG. 3 illustrates that the data driver 1200 is arranged to be adjacent to one side of the substrate 100. However, according to another embodiment, the data driver 1200 may be arranged on a flexible printed circuit board (“FPCB”) electrically connected to a pad arranged on one side of the display panel 10.

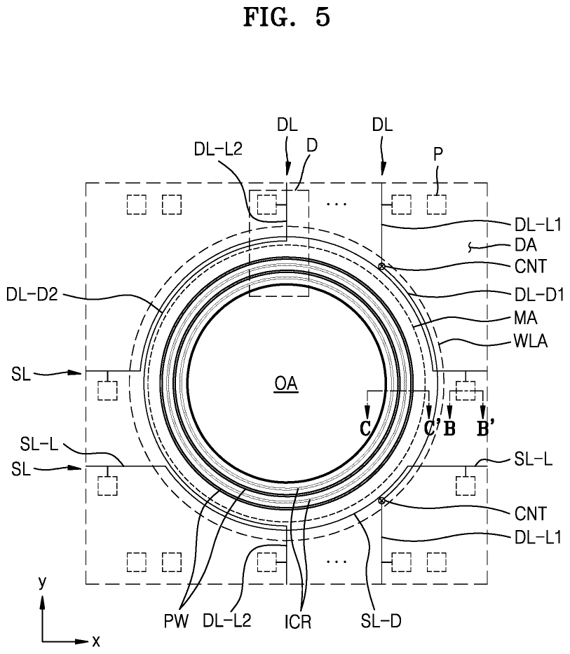

FIG. 5 is a plan view of a portion of the display panel 10 according to an embodiment.

Referring to FIG. 5, the middle area MA may be arranged between the opening area OA and the display area DA. Unlike the display area DA, the pixels P may not be arranged in the middle area MA. In a plan view, the middle area MA may be arranged to surround the opening area OA.

The pixels P may be arranged in the display area DA with the opening area OA between the pixels P. Some pixels P may be apart from each other with the opening OA therebetween, and the opening area OA may be defined between the pixels P. For example, in a plan view, the pixels P may be arranged above and below the opening area OA and the pixels P may be arranged on right and left sides of the opening area OA.

Signal lines adjacent to the opening area OA from among the signal lines configured to supply signals to the pixels P may bypass the opening area OA. Here, the signal lines bypassing the opening area OA may be arranged along an edge of the display area DA adjacent to the middle area MA. Hereinafter, an area in which the signal lines bypassing the opening area OA are arranged is defined as a line area WLA. The line area WLA may denote an edge area of the display area DA adjacent to the middle area MA.

In a plan view of FIG. 5, at least one data line DL from among the data lines crossing the display area DA may extend in a y direction to provide data signals to the pixels P arranged above and below the opening area OA and may bypass the opening area OA and the middle area MA along the edge of the display area DA. In a plan view, at least one scan line DL from among the scan lines crossing the display area DA may extend in an x direction to provide scan signals to the pixels P arranged on right and left sides of the opening area OA and may bypass the opening area OA and the middle area MA along the edge of the display area DA.

A circuitous portion or bypass portion SL-D of the scan line SL may be arranged on the same layer as an extension portion SL-L of the scan line SL crossing the display area DA and may be integrally formed with the extension portion SL-L. A circuitous portion or bypass portion DL-D1 of the at least one data line DL from among the data lines DL may be formed on a different layer from an extension portion DL-L1 of the data line DL crossing the display area DA. Also, the circuitous portion or bypass portion DL-D1 of the data line DL and the extension portion DL-L1 of the data line DL may contact each other through a contact hole CNT. A circuitous portion or bypass portion DL-D2 of the at least one data line DL from among the data lines DL may be arranged on the same layer as an extension portion DL-L2 of the data line DL and may be integrally formed with the extension portion DL-L2. Here, the circuitous portions or bypass portions SL-D, DL-D1, and DL-D2 may be referred as a “line portion”.

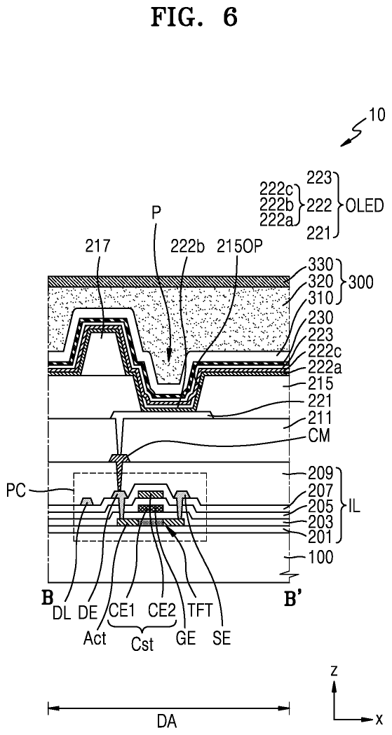

FIG. 6 is a schematic cross-sectional view of a portion of the display area DA of the display apparatus 1 according to an embodiment. A cross-sectional structure of the display area DA will be described by referring to the display panel 10 of FIG. 6. FIG. 6 may correspond to a cross-section of the display panel 10 taken along line B-B′ of FIG. 5.

The substrate 100 may include glass materials or polymer resins. According to an embodiment, the substrate 100 may include the plurality of layers described above. For example, the substrate 100 may have a structure including at least one organic layer and at least one inorganic layer alternately arranged.

A buffer layer 201 configured to prevent the penetration of impurities into a semiconductor layer Act of a thin-film transistor TFT may be formed on the substrate 100. The buffer layer 201 may include an inorganic insulating material, such as silicon nitride, silicon oxynitride, and silicon oxide. The buffer layer 201 may include a single layer or layers.

A pixel circuit PC may be arranged on the buffer layer 201. The pixel circuit PC may include the thin-film transistor TFT and a storage capacitor Cst. The thin-film transistor TFT may include the semiconductor layer Act, a gate electrode GE, a source electrode SE, and a drain electrode DE. The thin-film transistor TFT illustrated in FIG. 6 may be the driving thin-film transistor corresponding to the first thin-film transistor T1 described with reference to FIG. 4. The data line DL of the pixel circuit PC may be electrically connected to a switching thin-film transistor included in the pixel circuit PC, although not illustrated. According to the embodiment, a top gate-type in which the gate electrode GE is arranged on the semiconductor layer Act with a gate insulating layer 203 between the gate electrode GE and the semiconductor layer Act, is illustrated. However, according to another embodiment, the thin-film transistor TFT may be a bottom-gate type.

The semiconductor layer Act may include polysilicon. Alternatively, the semiconductor layer Act may include amorphous silicon, an oxide semiconductor, or an organic semiconductor.

The gate electrode GE may include a low-resistance metal material. The gate electrode GE may include a conductive material including Mo, Al, Cu, Ti, etc. and may include layers or a single layer.

The gate insulating layer 203 between the semiconductor layer Act and the gate electrode GE may include an inorganic insulating material, such as silicon oxide, silicon nitride, silicon oxynitride, aluminum oxide, titanium oxide, tantalum oxide, and hafnium oxide. The gate insulating layer 203 may include a single layer or layers including the materials described above.

The source electrode SE and the drain electrode DE, which are connection electrodes electrically connected to the semiconductor layer Act, may be arranged on the same layer as the data line DL and may include the same material as the data line DL. The source electrode SE, the drain electrode DE, and the data line DL may include a material having good conductivity. The source electrode S and the drain electrode D may include a conductive material including Mo, Al, Cu, Ti, etc., and may include layers or a single layer. According to an embodiment, the source electrode SE, the drain electrode DE, and the data line DL may include Ti/Al/Ti layers.

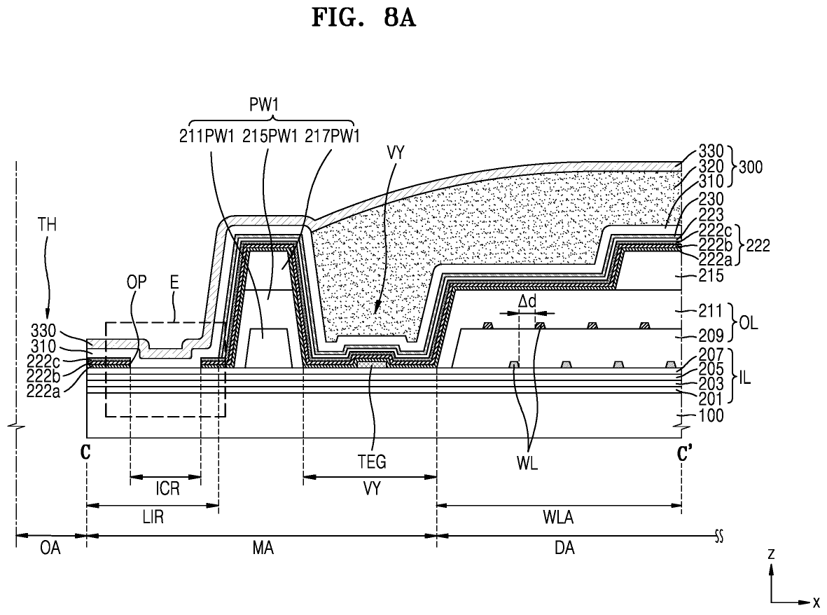

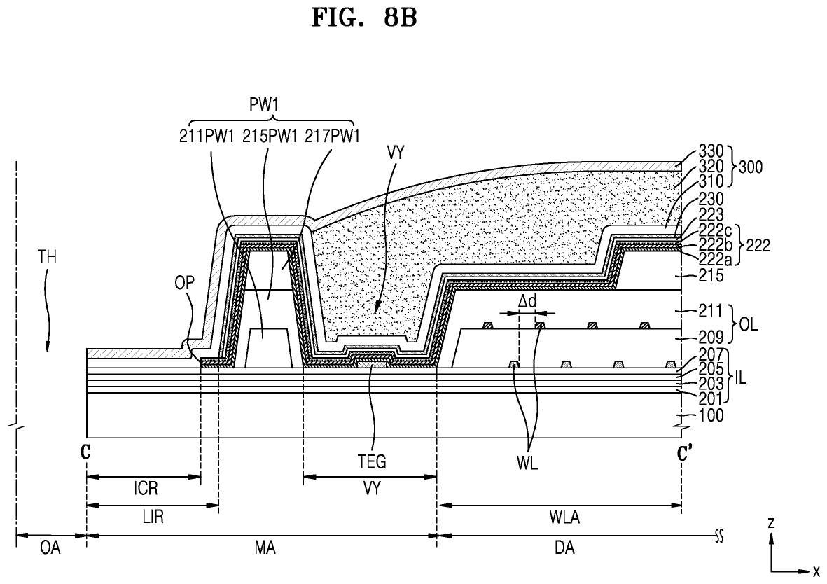

The storage capacitor Cst may include a lower electrode CE1 and an upper electrode CE2 overlapping each other with a first interlayer-insulating layer 205 therebetween. The storage capacitor Cst may overlap the thin-film transistor TFT in a plan view. With respect to this aspect, FIG. 8 illustrates that the gate electrode GE of the thin-film transistor TFT is the lower electrode CE1 of the storage capacitor Cst. According to another embodiment, the storage capacitor Cst may not overlap the thin-film transistor TFT in a plan view. The storage capacitor Cst may be covered by a second interlayer-insulating layer 207. The upper electrode CE2 of the storage capacitor Cst may include a conductive material including Mo, Al, Cu, Ti, etc. and may include layers or a single layer including the materials described above.

The first interlayer-insulating layer 205 and the second interlayer-insulating layer 207 may include an inorganic insulating material, such as silicon oxide, silicon nitride, silicon oxynitride, aluminum oxide, titanium oxide, tantalum oxide, and hafnium oxide. The first interlayer-insulating layer 205 and the second interlayer-insulating layer 207 may include a single layer or layers including the materials described above.

A first organic insulating layer 209 and a second organic insulating layer 211 may be arranged on the second interlayer-insulating layer 207. The first organic insulating layer 209 and the second organic insulating layer 211 may include approximately flat upper surfaces.

The pixel circuit PC may be electrically connected to a pixel electrode 221. For example, as illustrated in FIG. 8, a contact metal layer CM may be arranged between the pixel circuit PC and the pixel electrode 221. The contact metal layer CM may contact the pixel circuit PC through a contact hole formed in the first organic insulating layer 209, and the pixel electrode 221 may contact the contact metal layer CM through a contact hole formed in the second organic insulating layer 211 on the contact metal layer CM. The contact metal layer CM may include a conductive material including Mo, Al, Cu, Ti, etc. and may include layers or a single layer including the conductive materials described above. According to an embodiment, the contact metal layer CM may include Ti/Al/Ti layers.

The first organic insulating layer 209 and the second organic insulating layer 211 may include an organic insulating material, such as a general-purpose polymer, such as polymethylmethacrylate (“PMMA”) or polystyrene (“PS”), polymer derivatives having a phenol-based group, acryl-based polymers, imide-based polymers, arylether-based polymers, amide-based polymers, fluorine-based polymers, p-xylene-based polymers, vinyl alcohol-based polymers, and a blend thereof. According to an embodiment, the first organic insulating layer 209 and the second organic insulating layer 211 may include polyimide.

The pixel electrode 221 may be arranged on the second organic insulating layer 211. The pixel electrode 221 may include a conductive oxide, such as indium tin oxide (“ITO”), indium zinc oxide (“IZO”), zinc oxide (ZnO), indium oxide (In₂O₃), indium gallium oxide (“IGO”), or aluminum zinc oxide (“AZO”). According to another embodiment, the pixel electrode 221 may include a reflective layer including Ag, Mg, Al, Pt, Pd, Au, Ni, Nd, Ir, Cr, or a compound thereof. According to another embodiment, the pixel electrode 221 may further include a layer including ITO, IZO, ZnO or In₂O₃ above/below the reflective layer described above. For example, the pixel electrode 221 may include ITO/Ag/ITO layers.

A pixel-defining layer 215 may be arranged on the pixel electrode 221. The pixel-defining layer 215 may define an opening 2150P therein exposing an upper surface of the pixel electrode 221 and may cover an edge of the pixel electrode 221. The opening 2150P of the pixel-defining layer 215 may define an emission area. The pixel-defining layer 215 may include an organic insulating material. Alternatively, the pixel-defining layer 215 may include an inorganic insulating material, such as SiNₓ, SiON, or SiOₓ. Alternatively, the pixel-defining layer 215 may include an organic insulating material and an inorganic insulating material.

An intermediate layer 222 may include an emission layer 222b. The emission layer 222b may include a high molecular-weight or low molecular-weight organic material emitting a predetermined color of light. Also, the intermediate layer 222 may include one or more organic material layers below and/or above the emission layer 222b. According to an embodiment, the intermediate layer 222 may include a first common layer 222a arranged below the emission layer 222b and/or a second common layer 222c arranged above the emission layer 222b.

The first common layer 222a may include a layer or layers. For example, when the first common layer 222a includes a high molecular-weight material, the first common layer 222a may include a hole transport layer (“HTL”) having a single-layered structure and may include poly-(3,4)-ethylene-dihydroxy thiophene (“PEDOT”) or polyaniline (“PANI”). When the first common layer 222a includes a low molecular-weight material, the first common layer 222a may include a hole injection layer (“HIL”) and an HTL.

The second common layer 222c may not always be provided. For example, when the first common layer 222a and the emission layer 222b include high molecular-weight materials, it is desirable to form the second common layer 222c. The second common layer 222c may include a layer or layers. The second common layer 222c may include an electron transport layer (“ETL”) and/or an electron injection layer (“EIL”).

According to an embodiment, a thickness of the first common layer 222a may be the same as or greater than a thickness of the second common layer 222c. For example, the thickness of the first common layer 222a may be about 1100 Å to about 2200 Å, and the thickness of the second common layer 222c may be about 350 Å to about 2200 Å.

The emission layer 222b of the intermediate layer 222 may be arranged in each pixel in the display area DA. That is, the emission layer 222b may be patterned to correspond to the pixel electrode 221. The emission layer 222b may include an emission material layer including a high molecular-weight or low molecular-weight organic material emitting a predetermined color of light and an auxiliary layer for supporting a resonance distance of the emission material layer. The auxiliary layer may include a hole transport material, such as PEDOT or PANI. The emission material layer and the auxiliary layer may have different thicknesses from each other, depending on a color emitted by each color.

The intermediate layer 222 may be arranged not only in the display area DA, but also in the middle area MA. According to another embodiment, the emission layer 222b of the intermediate layer 222 may be arranged only in the display area DA.

An opposite electrode 223 may include a conductive material having a low work function. For example, the opposite electrode 223 may include a transparent (or transflective) layer including Ag, Mg, Al, Pt, Pd, Au, Ni, Nd, Ir, Cr, Li, Ca, or an alloy thereof. Alternatively, the opposite electrode 223 may further include a layer, such as ITO, IZO, ZnO, or In₂O₃, on the transparent (or transflective) layer including the material described above. The opposite electrode 223 may be formed not only in the display area DA, but also in the middle area MA. The first common layer 222a, the second common layer 222c, and the opposite electrode 223 may be formed by heat deposition.

A capping layer 230 may be arranged on the opposite electrode 223. For example, the capping layer 230 may include LiF and may be formed by heat deposition. According to some embodiments, the capping layer 230 may be omitted.

A spacer 217 may be formed on the pixel-defining layer 215. The spacer 217 may include an organic insulating material, such as polyimide. Alternatively, the spacer 217 may include an inorganic insulating material, or an organic insulating material and an inorganic insulating material.

The spacer 217 may include a different material from the pixel-defining layer 215 or the same material as the pixel-defining layer 215. For example, the pixel-defining layer 215 and the spacer 217 may be formed together by a mask process using a halftone mask. According to an embodiment, the pixel-defining layer 215 and the spacer 217 may include polyimide.

The organic light-emitting diode OLED may be covered by a thin-film encapsulation layer 300. The thin-film encapsulation layer 300 may include at least one organic encapsulation layer and at least one inorganic encapsulation layer. FIG. 6 illustrates that the thin-film encapsulation layer 300 includes first and second inorganic encapsulation layers 310 and 330 and an organic encapsulation layer 320 arranged between the first and second inorganic encapsulation layers 310 and 330. According to another embodiment, the number of organic encapsulation layers and the number of inorganic encapsulation layers and an order of stacks may be changed.

The first and second inorganic encapsulation layers 310 and 330 may include one or more inorganic materials from among aluminum oxide (Al₂O₃), titanium oxide (TiO), tantalum oxide (TA₂O₅), hafnium oxide (HfO₂), ZnO, SiOₓ, SiNₓ, and SiON. The first and second inorganic encapsulation layers 310 and 330 may include a single layer or layers including the materials described above.

The organic encapsulation layer 320 may include a polymer-based material. The polymer-based material may include acryl-based resins, epoxy-based resins, polyimide, polyethylene, etc. According to an embodiment, the organic encapsulation layer 320 may include acrylate.

Thicknesses of the first and second inorganic encapsulation layers 310 and 330 may be different from each other. The thicknesses of the first inorganic encapsulation layer 310 may be greater than the thickness of the second inorganic encapsulation layer 330. Alternatively, the thickness of the second inorganic encapsulation layer 330 may be greater than the thickness of the first inorganic encapsulation layer 310, or the thicknesses of the first and second inorganic encapsulation layer 310 and 330 may be the same as each other.

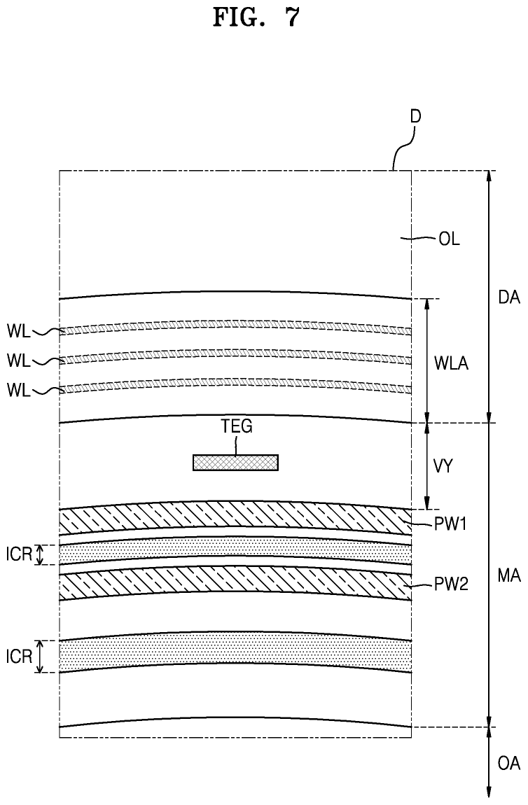

FIG. 7 is an enlarged plan view of region D of FIG. 5.

Referring to FIGS. 5 and 7 together, at least one partition wall PW may be arranged in the middle area MA. In a plan view, the partition wall PW may have a shape of a closed curve surrounding the opening area OA, for example, a ring shape. When a plurality of partition walls PW are provided, the plurality of partition walls PW may be arranged to be apart from each other. FIG. 5 illustrates that two partition walls PW are arranged in the middle area MA. The partition walls PW arranged in the middle area MA may prevent overflowing of the organic encapsulation layer 320 of FIG. 6 into the opening area OA.

The middle area MA may be an area for preventing impurities or water from flowing from the opening area OA to the display area DA, and at least a portion of the middle area MA may include an inorganic contact region ICR. The inorganic contact region ICR may be an area where a portion of the intermediate layer 222 is removed. The inorganic contact region ICR may be configured such that a lower inorganic layer and an upper inorganic layer may contact each other with the organic light-emitting diode OLED therebetween so that an organic layer may not be arranged between the lower inorganic layer and the upper inorganic layer, thereby preventing the penetration of impurities or water due to the organic layer. According to an embodiment, the lower inorganic layer may be at least one of the buffer layer 201, the gate insulating layer 203, the first interlayer-insulating layer 205, and the second interlayer-insulating layer 207 illustrated in FIG. 6, and the upper inorganic layer may be the first inorganic encapsulation layer 310 of the thin-film encapsulation layer 300.

Referring to FIG. 7, a metal unit TEG may be arranged in the middle area MA. The metal unit TEG may be arranged between the display area DA and the partition wall PW. The partition wall PW may include the first partition wall PW1 and the second partition wall PW2. The metal unit TEG may be arranged to be apart from the inorganic contact region ICR. FIG. 7 illustrates that the metal unit TEG is arranged between the display area DA and the first partition wall PW1, but the metal unit TEG is not limited thereto. The metal unit TEG may be arranged in an extra space of the middle area MA except for the inorganic contact region ICR.

The metal unit TEG may be arranged below the intermediate layer 222. The metal unit TEG may be arranged below the first common layer 222a included in the intermediate layer 222. The metal unit TEG may be arranged between the inorganic insulating layer IL and the intermediate layer 222. The metal unit TEG may be provided to have various shapes, such as a quadrangular shape, a polygonal shape, a circular shape, etc.

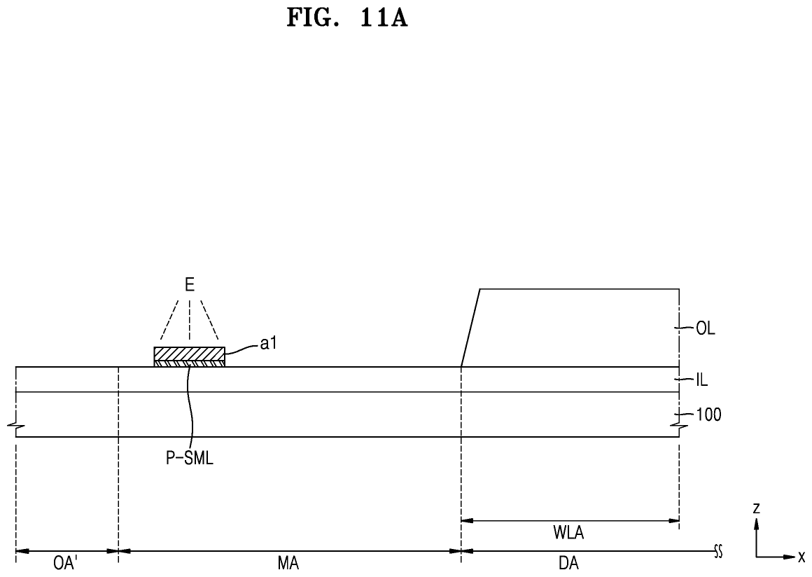

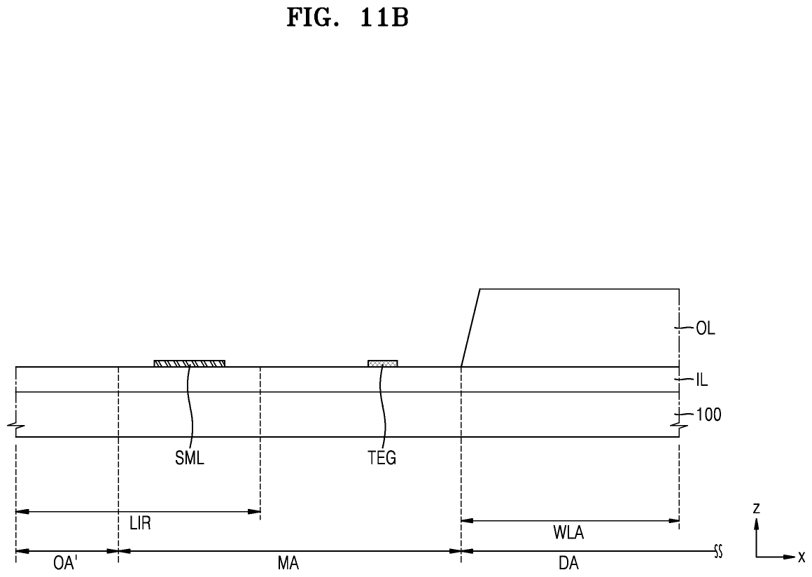

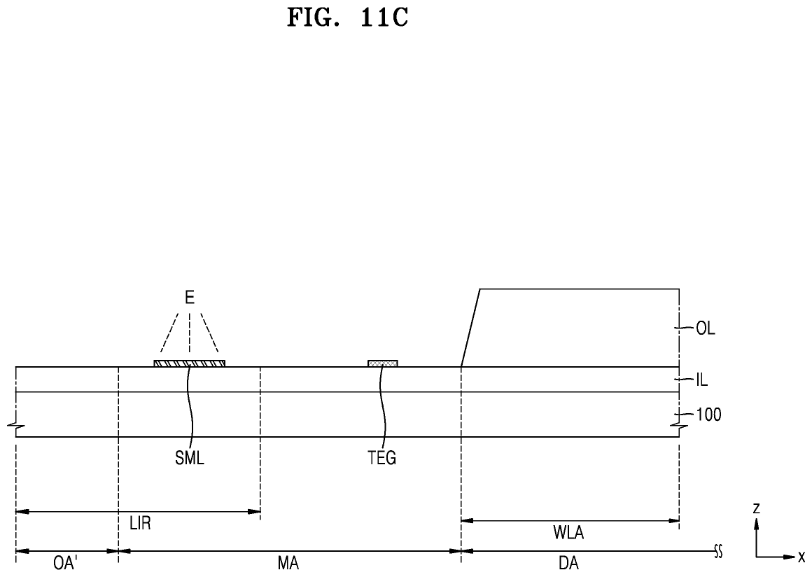

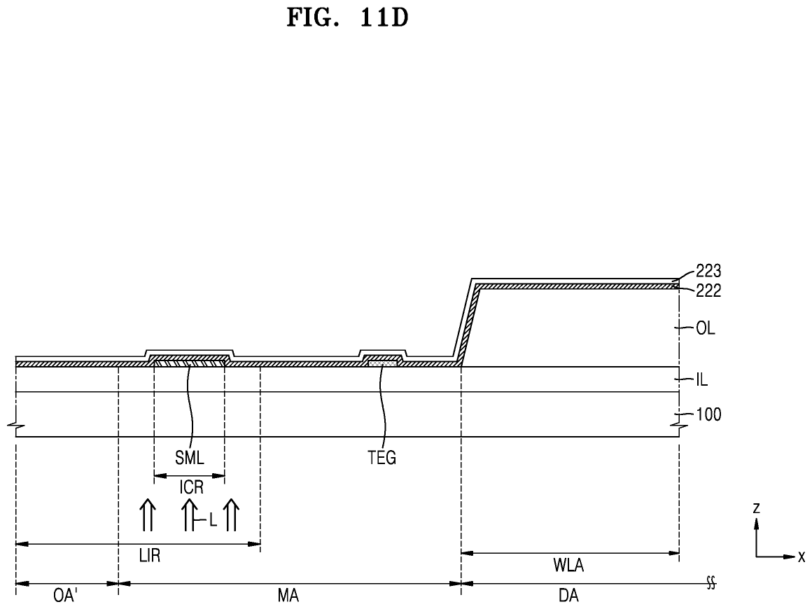

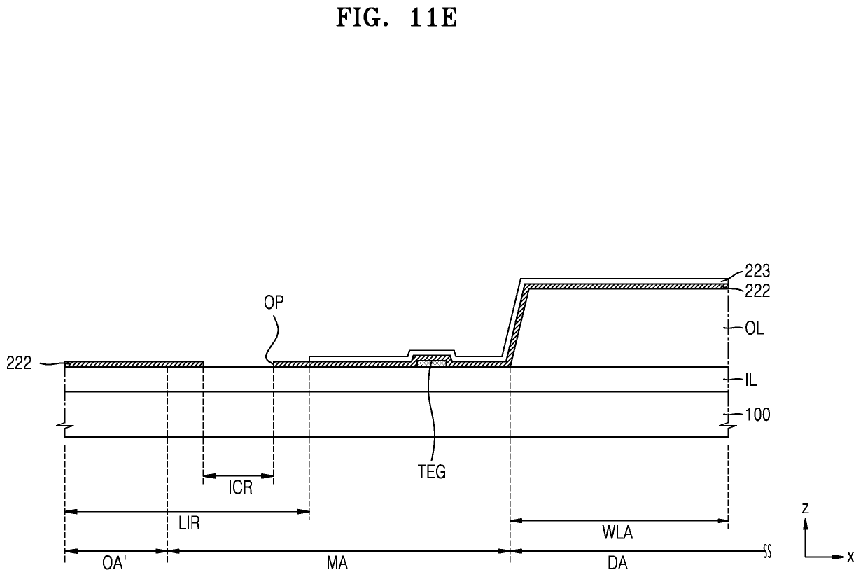

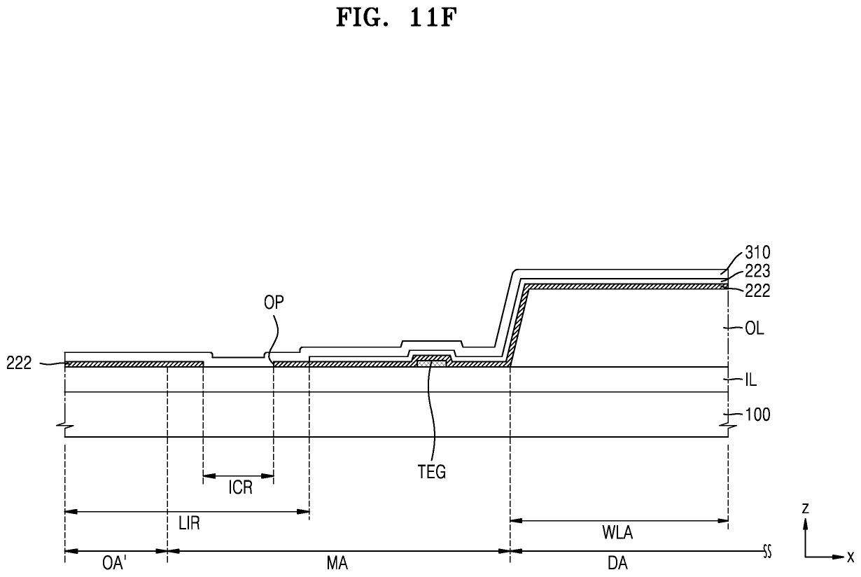

The metal unit TEG may be provided with respect to inspection of the display apparatus. The metal unit TEG may also be used for inspection in a process of manufacturing the display apparatus. The metal unit TEG may provide a reference for determining whether a predetermined material is included a certain layer (e.g., sacrificial metal layers SML in FIG. 11B) in the middle area MA or not. The predetermined material may be a material included in the metal unit TEG.

The metal unit TEG may be formed by ink-jetting a metal material. The metal unit TEG may include Al or Ag. A detailed description about the metal unit TEG is to be given below with reference to FIG. 8A.

FIGS. 8A and 8B are schematic cross-sectional views of portions of the display area DA and the middle area MA of the display apparatus 1 according to an embodiment.

Referring to FIG. 8A, the line area WLA and the middle area MA are described.

The first organic insulating layer 209 and the second organic insulating layer 211 may also be arranged in the line area WLA. According to the embodiment, the line area WLA may denote an edge area of the display area DA adjacent to the middle area MA. Also, according to the embodiment, the display area DA may be defined as an area including an area in which the first organic insulating layer 209 and/or the second organic insulating layer 211, which are/is (a) organic layer(s) as described above, are/is arranged.

Lines WL configured to supply signals to the pixel P may be arranged in the line area WLA. The lines WL may include the data line DL and/or the scan line SL and may correspond to the circuitous or bypass portions DL-D1 and DL-D2 and SL-D of the data line DL and the scan line SL in FIG. 5.

According to an embodiment, the lines WL may be alternately arranged with an insulating layer therebetween in the line area WLA. For example, one of adjacent lines WL may be arranged below the insulating layer (for example, the first organic insulating layer 209), and the other may be arranged above the insulating layer (for example, the first organic insulating layer 209). Like this, the lines WL may be alternately arranged. When the lines WL are alternately arranged with the insulating layer therebetween, a distance (Δd, a pitch) between the data lines DL may be reduced.

A portion of the multi-layered structure for forming the organic light-emitting diode OLED may be arranged and extend on the insulating layers in the line area WLA. The multi-layered structure may include the intermediate layer 222, the opposite electrode 223, and the capping layer 230. FIG. 8A continuously illustrates the emission layer 222b for convenience, but the emission layers 222b may be patterned and arranged to be apart from each other by a predetermined distance. The emission layer 222b arranged in the line area WLA may just include an emission material and does not actually emit light like the emission layers 222b included in the organic light-emitting diode OLED. According to an embodiment, the emission layer 222b of the intermediate layer 222 may not extend to the line area WLA.

The middle area MA may be arranged between the display area DA and the opening area OA and may include at least one partition wall, hereinafter, the first partition wall PW1, at least one inorganic contact region ICR, and at least one metal unit TEG. The middle area MA may prevent the penetration of impurities or water into the display area DA through the opening area OA.

The first partition wall PW1 may be arranged in the middle area MA. The first partition wall PW1 may be arranged on the inorganic insulating layer IL extending to the middle area MA. According to another embodiment, a sub-partition wall may further be arranged on the second organic insulating layer 211 in the line area WLA. Through the first partition wall PW1, overflowing of the organic encapsulation layer 320 of the thin-film encapsulation layer 300 into the opening area OA may be prevented.

According to an embodiment, the first partition wall PW1 may include first to third layers 211PW1, 215PW1, and 217PW1. The first layer 211PW1 of the first partition wall PW1 may include the same material as the first organic insulating layer 209 or the second organic insulating layer 211, the second layer 215PW1 may include the same material as the pixel-defining layer 215, and the third layer 217PW1 may include the same material as the spacer 217.

According to an embodiment, a valley VY may be formed between the first partition wall PW1 and the display area DA due to the first partition wall PW1. The valley VY may be formed by the first partition wall PW1 and an organic insulating layer OL in the display area DA.

The intermediate layer 222 may be arranged and extend in the middle area MA. The emission layer 222b arranged in the middle area MA may only include an emission material and may not actually emit light like the emission layers included in the organic light-emitting diode OLED. According to an embodiment, the emission layer 222b of the intermediate layer 222 may not extend to the middle area MA.

The intermediate layer 222 may be arranged on the first partition wall PW1. The intermediate layer 222 may be arranged to cover an upper surface and a side surface of the first partition wall PW1. The intermediate layer 222 may be arranged along a shape of the valley VY. The first and second inorganic encapsulation layers 310 and 330 may be arranged on the intermediate layer 222 on the first partition wall PW1.

The intermediate layer 222 may define an opening portion OP in the middle area MA therein. The opening portion OP may include at least one opening. The opening portion OP may be provided by removing a portion of the intermediate layer 222. The opening portion OP may be arranged between the first partition wall PW1 and the opening area OA.

The middle area MA may include a laser irradiation region LIR. The laser irradiation region LIR may be an area onto which laser rays are irradiated to remove, during the manufacturing process, part or all of the layered structure arranged in the middle area MA, that is, the intermediate layer 222, the opposite electrode 223, and the capping layer 230.

The opening portion OP of the intermediate layer 222 may be formed by irradiating laser rays onto the laser irradiation region LIR after forming a sacrificial metal layer (See SML in FIG. 11B) between the intermediate layer 222 and the inorganic insulating layer IL. By absorbing the laser rays irradiated from the substrate 100, the sacrificial metal layer may be removed together with the intermediate layer 222 corresponding to the sacrificial metal layer. Thus, the opening portion OP may expose a portion of the inorganic insulating layer IL below the opening portion OP.

At least one inorganic contact region ICR may be arranged in the middle area MA. The inorganic contact region ICR may be provided to have a shape of a closed curve along a shape of the opening area OA, as described above with reference to FIG. 5. The inorganic contact region ICR may be arranged in the laser irradiation region LIR.

The inorganic contact region ICR may be an area in which only the inorganic insulating layer IL is arranged between the first inorganic encapsulation layer 310 and the substrate 100. In other words, to correspond to the inorganic contact region ICR, the inorganic insulating layer IL may be arranged on the substrate 100, and the first inorganic encapsulation layer 310 may be in direct contact with the inorganic insulating layer IL.

The inorganic contact region ICR may be formed such that an upper surface of the inorganic insulating layer IL exposed through the opening portion OP of the intermediate layer 222 contacts the first inorganic encapsulation layer 310. That is, the inorganic contact region ICR may be defined by the opening portion OP.

The display apparatus 1 according to an embodiment may include the metal unit TEG arranged in the middle area MA. The metal unit TEG may be arranged in an extra space of the middle area MA apart from the opening portion OP of the intermediate layer 222. According to an embodiment, the metal unit TEG may be arranged between the first partition wall PW1 and the display area DA. That is, the metal unit TEG may overlap the valley VY.

The metal unit TEG may overlap the intermediate layer 222 in a plan view. The metal unit TEG may be arranged below the intermediate layer 222. The metal unit TEG may be arranged below the first common layer 222a included in the intermediate layer 222. The metal unit TEG may be arranged between the inorganic insulating layer IL and the first common layer 222a.

The metal unit TEG may be provided for reliability inspection of the display apparatus 1.

The metal unit TEG may be formed by ink-jetting a metal material. The metal unit TEG may include a first material. The first material may include Al or Ag. The metal unit TEG may provide a reference value with respect to the first material (a1 in FIG. 11A). Whether or not the first material remains may be determined by comparing reflected light values of the metal unit TEG and an inspection object obtained through an optical inspector.

The metal unit TEG may also be used for inspection during a manufacturing process.

As described above, the opening portion OP of the intermediate layer 222 may be formed by irradiating laser rays after forming a sacrificial metal layer between the inorganic insulating layer IL and the intermediate layer 222. A portion of the intermediate layer 222, the portion corresponding to the sacrificial metal layer, may be removed together with the sacrificial metal layer. Thus, the intermediate layer 222 may include the opening portion OP.

When the sacrificial metal layer includes a predetermined material (hereinafter, a first material) having a high reflectivity, laser rays irradiated to the substrate 100 to form the opening portion OP may be reflected and distributed toward the substrate 100 again due to the sacrificial metal layer. Accordingly, damage may occur to a layer (for example, the substrate 100, etc.) below the sacrificial metal layer.

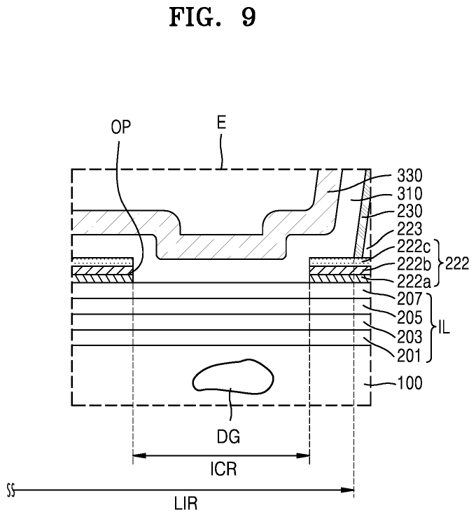

FIG. 9 is a cross-sectional view of a display apparatus which may be formed when the opening portion OP is formed by irradiating laser rays while the sacrificial metal layer includes the first material. In this case, as illustrated in FIG. 9, damage DG may occur to a layer arranged below the intermediate layer 222. When the damage DG occurs to the layer arranged below the intermediate layer 222, defects resulting from this may occur during use of the display apparatus 1.

To prevent this phenomenon, before irradiating the laser rays to form the opening portion OP of the intermediate layer 222, whether or not the first material of the sacrificial metal layer remains may be determined by using an optical inspector. The optical inspector may measure a value of reflected light of an inspection area. However, the value measured through the optical inspector may be affected by an environmental change, such as illumination, etc., and thus, due to the vagueness of the value measured through the optical inspector, it may be difficult to determine whether or not the first material remains in the sacrificial metal layer.

Referring to FIG. 8A again, according to an embodiment, the metal unit TEG may be provided.

The metal unit TEG may be formed by ink-jetting a metal material. The metal unit TEG may include Al or Ag. Al or Ag may be the first material having a high reflectivity. By comparing the reflected light values of the metal unit TEG and the sacrificial metal layer (SML in FIG. 11B) obtained through the optical inspector, whether or not the first material remains in the sacrificial metal layer may be determined. That is, regardless of the change of an inspection environment, whether or not the first material remains in the sacrificial metal layer may be determined. When it is determined that the first material remains in the sacrificial metal layer, a process of removing the first material in the sacrificial metal layer may be additionally performed.

That is, the display apparatus according to the embodiment may include the metal unit TEG in the middle area MA, and thus, may suppress or minimize the damage to the layers below the intermediate layer 222 during a laser process.

Referring to FIG. 8A, the opposite electrode 223 and the capping layer 230 may be arranged on the intermediate layer 222. The opposite electrode 223 and the capping layer 230 extending to the middle area MA may be removed in the laser irradiation region LIR. In other words, the opposite electrode 223 and the capping layer 230 may not be arranged on the laser irradiation region LIR. As described above, the opposite electrode 223 and the capping layer 230 may be removed from the laser irradiation region LIR arranged in the middle area MA, and the intermediate layer, which is an organic material layer, may be removed from the inorganic contact region ICR, and thus, the penetration of impurities or water into the display area DA through the opening area OA may be effectively blocked.

FIG. 8B is a schematic cross-sectional view of portions of the display area DA and the middle area MA of the display apparatus 1 according to an embodiment. FIG. 8B illustrates a modified example of FIG. 8A.

Unlike FIG. 8A, which illustrates that the intermediate layer 222 is arranged between the inorganic contact region ICR and the opening area OA, FIG. 8B illustrates that the intermediate layer 222 is not arranged between the inorganic contact region ICRD and the opening area OA. In this case, the inorganic contact region ICR may be substantially the same as the laser irradiation region LIR.

This is because FIG. 8B illustrates an embodiment, according to which the sacrificial metal layer for forming the inorganic contact region ICR may continually extend to the opening area OA. In other words, in FIG. 8A, the sacrificial metal layer having a ring shape in a plan view may be used, and in FIG. 8B, the sacrificial metal layer formed to have a circular shape in a plan view may be used.

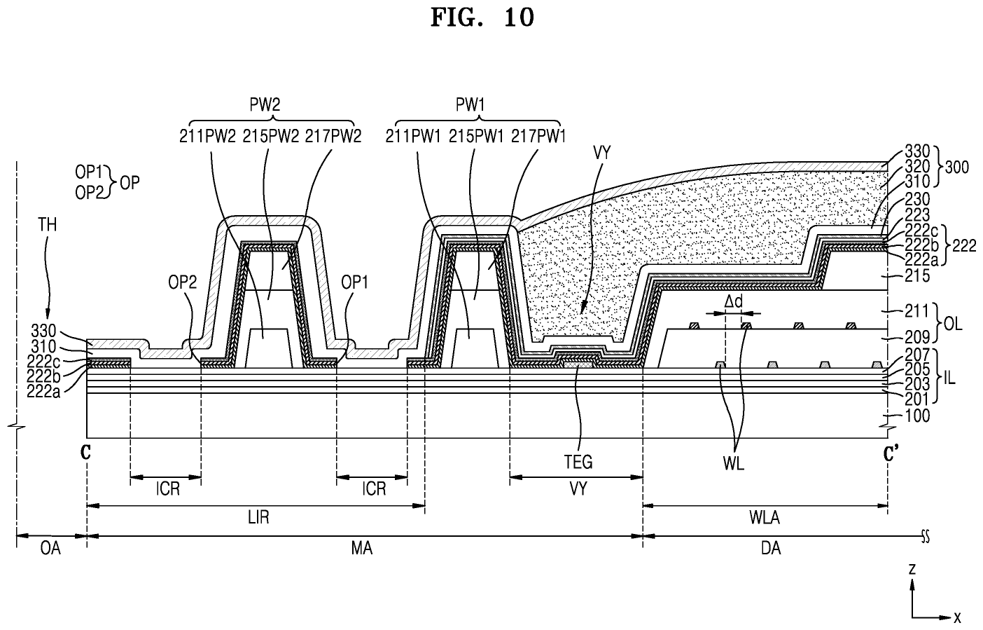

FIG. 10 is a schematic cross-sectional view of a portion of the display panel 10 according to an embodiment. FIG. 10 illustrates a modified example of FIG. 8A. FIG. 10 differs from FIG. 8A described above in that the first partition wall PW1 and a second partition wall PW2 may be arranged in the middle area MA. Hereinafter, the difference from FIG. 8A is mainly described, and the same aspects are not repeated based on the description with respect to FIG. 8A.

Referring to FIG. 10, the first partition wall PW1 and the second partition wall PW2 may be arranged in the middle area MA. The first partition wall PW1 and the second partition wall PW2 may be arranged to be apart from each other by a predetermined distance. The first partition wall PW1 and the second partition wall PW2 may be arranged on the inorganic insulating layer IL extending to the middle area MA. Through the first partition wall PW1 and the second partition wall PW2, overflowing of the organic encapsulation layer 320 of the thin-film encapsulation layer 300 into the opening area OA may be prevented.

According to an embodiment, the first partition wall PW1 may include the first to third layers 211PW1, 215PW1, and 217PW1. Also, the second partition wall PW2 may include first to third layers 211PW2, 215PW2, and 217PW2 similarly to the first partition wall PW1. The first layers 211PW1 and 211PW2 of the first partition wall PW1 and the second partition wall PW2 may include the same material as the first organic insulating layer 209 or the second organic insulating layer 211, the second layers 215PW1 and 215PW2 may include the same material as the pixel-defining layer 215, and the third layers 217PW1 and 217PW2 may include the same material as the spacer 217.

The intermediate layer 222 may be arranged on the first partition wall PW1 and the second partition wall PW2. The intermediate layer 222 may extend to the opening area OA and may be arranged to cover upper surfaces and side surfaces of the first partition wall PW1 and the second partition wall PW2. The first and second inorganic encapsulation layers 310 and 330 may be arranged on the intermediate layer 222 on the first partition wall PW1 and the second partition wall PW2.

At least one inorganic contact region ICR may be arranged in the middle area MA. In FIG. 10, the inorganic contact region ICR may be provided in a multiple number. The inorganic contact region ICR may be arranged between the first partition wall PW1 and the second partition wall PW2 and between the second partition wall PW2 and the opening area OA.

According to an embodiment, the intermediate layer 222 may have a first opening OP1 and a second opening OP2 each corresponding to the inorganic contact region ICR. According to an embodiment, the first opening OP1 may be arranged between the first partition wall PW1 and the second partition wall PW2, and the second opening OP2 may be arranged between the first partition wall PW1 and the opening area OA. The inorganic insulating layer IL below the first and second openings OP1 and OP2 may be exposed through the first and second openings OP1 and OP2. As described above, the inorganic insulating layer IL exposed through the first opening OP1 and the second opening OP2 may contact the first inorganic encapsulation layer 310. Accordingly, the first opening OP1 and the second opening OP2 may form the inorganic contact region ICR. Because the inorganic contact region ICR is provided in a multiple number, water penetration through the opening area OA may be prevented in a stepwise way.

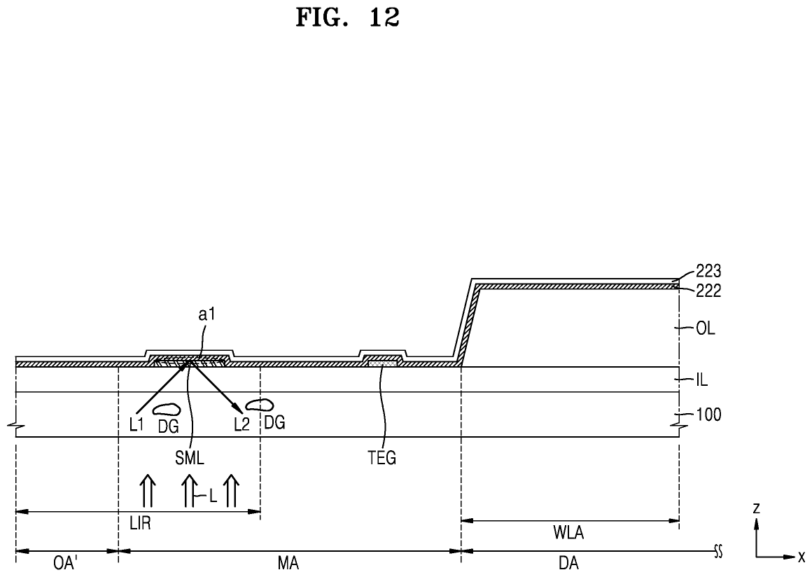

FIGS. 11A through 11F are schematic cross-sectional views for describing part of a manufacturing process of the display apparatus 1, according to an embodiment. FIG. 12 is a cross-sectional view showing reflection of a laser ray which may occur in the manufacturing process of the display apparatus 1.

The display apparatus 1 according to an embodiment may be formed on the substrate 100 approximately according to a stack order in a +z direction, as illustrated in the cross-sectional views of FIGS. 8A and 10 described above. Hereinafter, the same aspects are basically omitted based on the cross-sectional views above, and features with respect to the manufacturing process are mainly described with reference to FIGS. 11A to 11F.

Referring to FIG. 11A, the substrate 100 including the opening area OA, the display area DA at least partially surrounding the opening area OA, and the middle area MA between the opening area OA and the display area DA may be prepared. In FIG. 11A, a through-hole TH as shown in FIG. 8A, etc. is not yet formed in the opening area OA, and thus, the opening area OA may be referred to as a first area OA′. For convenience of explanation, the partition wall PW illustrated in FIG. 9, etc. is omitted in the middle area MA illustrated in FIGS. 11A to 11F. However, it may be understood that the partition wall PW may be arranged between the sacrificial metal layers SML.

The inorganic insulating layer IL may be formed on the entire surface of the substrate 100, and the organic insulating layer OL may be formed to correspond to the display area DA. The inorganic insulating layer IL may include at least one of the buffer layer 201, the gate insulating layer 203, the first interlayer-insulating layer 205, and the second interlayer-insulating layer 207 of FIG. 8A, etc. The organic insulating layer OL may be the first organic insulating layer 209 and/or the second organic insulating layer 211 in FIG. 8A, etc.

A metal layer P-SML including a first material a1 may be formed on the inorganic insulating layer IL corresponding to the middle area MA. The metal layer P-SML including the first material a1 may be etched (E) to remove the first material a1. The first material a1 may include Al or Ag.

The metal layer P-SML may be etched to form the sacrificial metal layer SML of FIG. 11B. The sacrificial metal layer SML may be provided to remove the intermediate layer 222 (see FIGS. 11D and 11E). An area in which the sacrificial metal layer SML is formed may correspond to the inorganic contact region ICR of FIG. 8A, etc. in the display apparatus 1. The sacrificial metal layer SML may be arranged in the laser irradiation region LIR of FIG. 8A, etc.

Referring to FIG. 11B, after the sacrificial metal layer SML is formed, the metal unit TEG including the first material a1 may be formed. The metal unit TEG may be formed in an area except for the laser irradiation region LIR of FIG. 8A, etc.

After forming the metal unit TEG, inspection values with respect to the first material a1 of the sacrificial metal layer SML and the first material a1 of the metal unit TEG may be compared, by using an optical inspector. The inspection values may be reflected light values of the sacrificial metal layer SML and the metal unit TEG. By comparing the inspection values, whether or not the first material a1 remains in the sacrificial metal layer SML after etching may be determined, regardless of a change of an inspection environment.

As illustrated in FIG. 11C, when it is determined that the first material a1 remains in the sacrificial metal layer SML, re-etching E of a portion of the sacrificial metal layer SML may be added.

Referring to FIG. 11D, the intermediate layer 222 may be formed to cover the sacrificial metal layer SML and the metal unit TEG. The opposite electrode 223 may be formed to cover the intermediate layer 222. Thereafter, a laser ray L may be irradiated to a portion of the substrate 100 to correspond to the laser irradiation region LIR. According to an embodiment, the laser ray L may be an infrared laser ray.

A method of manufacturing the display apparatus, according to an embodiment, may include removing the first material a1 in the sacrificial metal layer SML by referring the metal unit TEG such that the remaining first material a1 in the sacrificial metal layer SML is of a value less than or equal to a reference value, and thus, the reflection of the laser ray L due to the sacrificial metal layer SML may be minimized.

When the first material a1, which is any one of Al and Ag, remains in the sacrificial metal layer SML, the sacrificial metal layer SML may reflect and distribute the laser ray L1 as illustrated in FIG. 12. The reflected or distributed light L2 may cause damage DG to the substrate 100, etc. below the sacrificial metal layer SML.

Referring to FIG. 11E, by irradiating the laser ray L toward a portion of the substrate 100 to correspond to the laser irradiation region LIR, a metal layer, such as the opposite electrode 223, arranged on the laser irradiation region LIR, may be removed. The opposite electrode 223 may be simultaneously removed in a process of removing the sacrificial metal layer SML.

In this process, to remove the intermediate layer 222, which is an organic material layer, the sacrificial metal layer SML may be formed, as shown in FIGS. 11B to 11D. That is, the intermediate layer 222 arranged on the sacrificial metal layer SML may be removed together with the sacrificial metal layer SML when the sacrificial metal layer SML is removed.

To correspond to an area where the sacrificial metal layer SML is removed, the opening portion OP may be formed in the intermediate layer 222. Through the opening portion OP, the inorganic insulating layer IL below the opening portion OP may be exposed. The opening portion OP may disconnect the intermediate layer 222, which is the organic material layer. The organic material layer may be vulnerable to impurities or water, and thus, by disconnecting the intermediate layer 222 through the opening portion OP, the impurities or water which may penetrate into the display area DA through the organic material layer may be easily blocked.

Referring to FIG. 11F, the first inorganic encapsulation layer 310 may be formed on the opposite electrode 223. The first inorganic encapsulation layer 310 may be formed on the entire surface of the substrate 100. The first inorganic encapsulation layer 310 may contact a portion of the inorganic insulating layer IL exposed through the opening portion OP. Thus, the inorganic contact region ICR may be formed to correspond to the opening portion OP.

Thereafter, as shown in FIG. 8A, etc. described above, the organic encapsulation layer 320 and the second inorganic encapsulation layer 330 may be sequentially formed on the first inorganic encapsulation layer 310. Thereafter, the first area OA′ of FIG. 11F may be laser-cut, so that the through-hole TH may be formed in the opening area OA, as shown in FIG. 8A, etc.

As described above, according to the one or more of the above embodiments of the disclosure, the display apparatus including the display area in which various types of components are arranged and having improved reliability and the method of manufacturing the display apparatus may be realized. However, the scope of the disclosure is not limited to this effect as described above.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a substrate including an opening area, a display area surrounding at least a portion of the opening area, and a middle area between the opening area and the display area;
a display element arranged in the display area and comprising a pixel electrode, an opposite electrode on the pixel electrode, and an intermediate layer arranged between the pixel electrode and the opposite electrode; and
a metal unit arranged in the middle area and arranged between the substrate and the intermediate layer extending to the middle area.

2. The display apparatus of claim 1, further comprising an inorganic insulating layer arranged between the substrate and the intermediate layer to correspond to the display area and the middle area,
wherein the metal unit is arranged between the inorganic insulating layer and the intermediate layer.

3. The display apparatus of claim 1, wherein the metal unit includes aluminum (Al) or silver (Ag).

4. The display apparatus of claim 1, further comprising a first partition wall arranged in the middle area to surround the opening area,
wherein the metal unit is arranged between the first partition wall and the display area.

5. The display apparatus of claim 4, wherein an opening portion penetrating the intermediate layer is defined in the intermediate layer, and
the opening portion is arranged between the first partition wall and the opening area.

6. The display apparatus of claim 5, wherein the metal unit is arranged to be apart from the opening portion.

7. The display apparatus of claim 5, further comprising a second partition wall arranged in the middle area to be apart from the first partition wall,
wherein the opening portion includes a first opening arranged between the first partition wall and the second partition wall and a second opening arranged between the second partition wall and the opening area.

8. The display apparatus of claim 5, further comprising an inorganic encapsulation layer arranged on the intermediate layer to correspond to the display area and the middle area,
wherein the inorganic encapsulation layer is in direct contact with an inorganic insulating layer exposed through the opening portion.

9. The display apparatus of claim 8, further comprising a capping layer arranged between the opposite electrode and the inorganic encapsulation layer.

10. The display apparatus of claim 1, wherein the intermediate layer comprises a first common layer, an emission layer, and a second common layer, which are sequentially arranged on the pixel electrode.

11. The display apparatus of claim 1, further comprising a line portion arranged in the display area to be adjacent to the middle area so as to bypass the opening area.

12. A method of manufacturing a display apparatus, the method comprising:
preparing a substrate including a certain area, a display area surrounding at least a portion of the certain area, and a middle area between the certain area and the display area;
forming a sacrificial metal layer on a laser irradiation region in the middle area;
forming a metal unit including a first material on a region in the middle area, except for the laser irradiation region;
forming an intermediate layer to cover the sacrificial metal layer;
forming an opposite electrode to cover the intermediate layer; and
removing the sacrificial metal layer and a portion of the intermediate layer formed on the sacrificial metal layer, by irradiating a laser ray onto the laser irradiation region.

13. The method of claim 12, wherein the forming of the sacrificial metal layer includes:
forming a metal layer including the first material; and
removing the first material of the metal layer.

14. The method of claim 13, further comprising:
after the forming of the metal unit, determining whether or not the first material of the sacrificial metal layer remains, by comparing inspection values with respect to the first material of the sacrificial metal layer and the first material of the metal unit.

15. The method of claim 14, wherein the inspection values are values of reflected light extracted through an optical inspector.

16. The method of claim 14, wherein the first material includes aluminum (Al) or silver (Ag).

17. The method of claim 12, further comprising:
after the forming of the metal unit, etching a portion of the sacrificial metal layer.

18. The method of claim 12, wherein an opening portion of the intermediate layer is formed by removing the portion of the intermediate layer together with the sacrificial metal layer.

19. The method of claim 18, further comprising:
forming an inorganic encapsulation layer on the opposite electrode,
wherein the inorganic encapsulation layer is in direct contact with an inorganic insulating layer exposed through the opening portion of the intermediate layer.

20. The method of claim 12, further comprising:
removing a portion of the opposite electrode by irradiating the laser ray onto the laser irradiation region; and
forming a through-hole corresponding to the certain area of the substrate,
wherein the portion of the opposite electrode is simultaneously removed when the sacrificial metal layer is removed.
